(19) United States
(12) Patent Application Publication
(10) Pub. No.: US 2020/0396402 A1
(43) Pub. Date: Dec. 17, 2020

(54) IMAGE SENSORS HAVING BOOST CURRENT CONTROL CIRCUITRY FOR COLUMN SETTLING SPEEDUP

(71) Applicant: SEMICONDUCTOR COMPONENTS INDUSTRIES, LLC, Phoenix, AZ (US)

(72) Inventor: Tom FRESON, Leuven (BE)

(73) Assignee: SEMICONDUCTOR COMPONENTS INDUSTRIES, LLC, Phoenix, AZ (US)

(21) Appl. No.: 16/502,381

(22) Filed: Jul. 3, 2019

Related U.S. Application Data
(60) Provisional application No. 62/860,308, filed on Jun. 12, 2019.

(51) Int. Cl. H04N 5/369; H01L 27/146; H04N 5/378

(52) U.S. Cl. CPC H04N 5/3698; H01L 27/14612; H01L 27/14621; H01L 27/14643; H04N 5/378; H01L 27/14636

(57) ABSTRACT

An image sensor may include an array of imaging pixels arranged in rows and columns. Each column of imaging pixels may be coupled to a respective column output line. Each column output line may be coupled to a respective first current source. To decrease the settling time of the column output line, each column output line may be selectively coupled to a respective second current source during readout. Boost current control circuitry may control a transistor that applies the current from the second current source to the column output line. The boost current control circuitry may include a comparator that compares the actual current of the imaging pixels to a target current for the imaging pixels. Logic circuitry may use the output of the comparator to control the boost current enable transistor.

### CROSS-REFERENCE TO RELATED APPLICATIONS

This application claims the benefit of U.S. Provisional Patent Application No. 62/860,308, filed on Jun. 12, 2019, the entire contents of which is incorporated herein by reference.

### BACKGROUND

This relates generally to imaging devices, and more particularly, to imaging sensors having column lines for pixel readout.

Image sensors are commonly used in electronic devices such as cellular telephones, cameras, and computers to capture images. In a typical arrangement, an image sensor includes an array of image pixels arranged in pixel rows and pixel columns. Circuitry may be coupled to each pixel column for reading out image signals from the image pixels.

As image sensors increase in both pixel resolution and frame rate, the amount of time available to read out signals from each row in the image sensor decreases. If care is not taken, there may be insufficient time to properly readout out signals from the image sensor. In these situations, signals may be undesirably attenuated or undesirably large power consumption levels may be needed to readout signals without attenuation.

It would therefore be desirable to be able to provide improved readout techniques that allow for the sampling of unattenuated signals during short time frames.

### BRIEF DESCRIPTION OF THE DRAWINGS

FIG. 1 is a diagram of an illustrative electronic device having an image sensor in accordance with an embodiment.

FIG. 2 is a diagram of an illustrative pixel array and associated readout circuitry for reading out image signals in an image sensor in accordance with an embodiment.

FIG. 3 is a diagram of an illustrative image sensor with an imaging pixel and boost current control circuitry in accordance with an embodiment.

FIG. 4 is a diagram of an illustrative image sensor showing how the boost current control circuitry of FIG. 3 may include a comparator and logic circuitry in accordance with an embodiment.

FIG. 5 is a flowchart of illustrative steps for operating an image sensor of the type shown in FIG. 4 during readout in accordance with an embodiment.

FIG. 6 is a diagram of an illustrative image sensor with clamping circuitry in addition to boost current control circuitry in accordance with an embodiment.

### DETAILED DESCRIPTION

Embodiments of the present invention relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the pixels and readout circuitry for reading out image signals corresponding to the electric charge generated by the photosensitive elements.

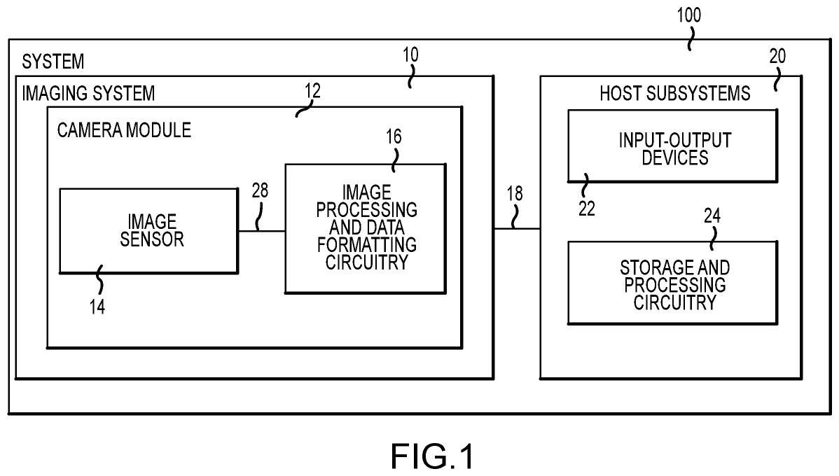

FIG. 1 is a diagram of an illustrative imaging and response system including an imaging system that uses an image sensor to capture images. System 100 of FIG. 1 may be an electronic device such as a camera, a cellular telephone, a video camera, or other electronic device that captures digital image data, may be a vehicle safety system (e.g., an active braking system or other vehicle safety system), or may be a surveillance system.

As shown in FIG. 1, system 100 may include an imaging system such as imaging system 10 and host subsystems such as host subsystem 20. Imaging system 10 may include camera module 12. Camera module 12 may include one or more image sensors 14 and one or more lenses.

Each image sensor in camera module 12 may be identical or there may be different types of image sensors in a given image sensor array integrated circuit. During image capture operations, each lens may focus light onto an associated image sensor 14. Image sensor 14 may include photosensitive elements (i.e., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), address circuitry, etc.

Still and video image data from camera sensor 14 may be provided to image processing and data formatting circuitry 16 via path 28. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common semiconductor substrate (e.g., a common silicon image sensor integrated circuit die). If desired, camera sensor 14 and image processing circuitry 16 may be formed on separate semiconductor substrates. For example, camera sensor 14 and image processing circuitry 16 may be formed on separate substrates that have been stacked.

Imaging system 10 (e.g., image processing and data formatting circuitry 16) may convey acquired image data to host subsystem 20 over path 18. Host subsystem 20 may include processing software for detecting objects in images, detecting motion of objects between image frames, determining distances to objects in images, filtering or otherwise processing images provided by imaging system 10.

If desired, system 100 may provide a user with numerous high-level functions. In a computer or advanced cellular telephone, for example, a user may be provided with the ability to run user applications. To implement these functions, host subsystem 20 of system 100 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid-state drives, etc.). Storage and processing circuitry 24 may also include microprocessors, microcontrollers, digital signal processors, application specific integrated circuits, etc.

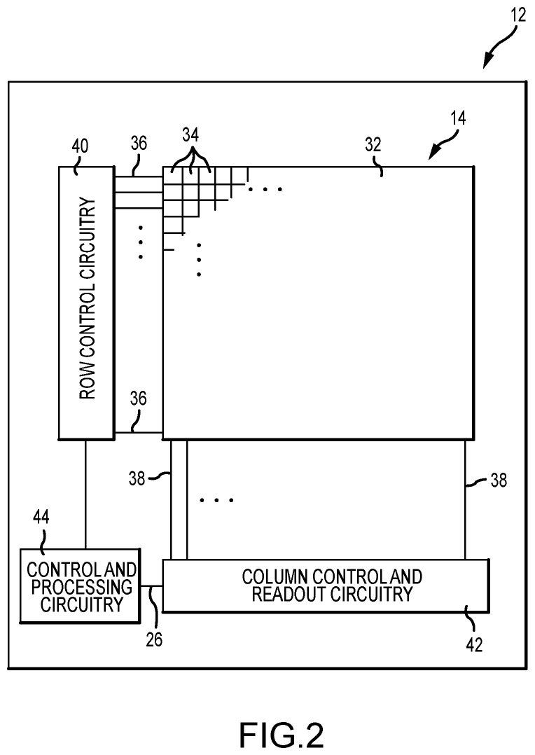

An example of an arrangement for camera module 12 of FIG. 1 is shown in FIG. 2. As shown in FIG. 2, camera module 12 includes image sensor 14 and control and processing circuitry 44. Control and processing circuitry 44 may correspond to image processing and data formatting circuitry 16 in FIG. 1. Image sensor 14 may include a pixel array such as array 32 of pixels 34 (sometimes referred to herein as image sensor pixels, imaging pixels, or image pixels 34) and may also include control circuitry 40 and 42. Control and processing circuitry 44 may be coupled to row control circuitry 40 and may be coupled to column control and readout circuitry 42 via data and control path 26. Row control circuitry 40 may receive row addresses from control and processing circuitry 44 and may supply corresponding row control signals to image pixels 34 over control paths 36 (e.g., dual conversion gain control signals, pixel reset control signals, charge transfer control signals, blooming control signals, row select control signals, or any other desired pixel control signals). Column control and readout circuitry 42 may be coupled to the columns of pixel array 32 via one or more conductive lines such as column lines 38. Column lines 38 may be coupled to each column of image pixels 34 in image pixel array 32 (e.g., each column of pixels may be coupled to a corresponding column line 38). Column lines 38 may be used for reading out image signals from image pixels 34 and for supplying bias signals (e.g., bias currents or bias voltages) to image pixels 34. During image pixel readout operations, a pixel row in image pixel array 32 may be selected using row control circuitry 40 and image data associated with image pixels 34 of that pixel row may be read out by column control and readout circuitry 42 on column lines 38.

Column control and readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and column memory for storing the read out signals and any other desired data. Column control and readout circuitry 42 may output digital pixel values to control and processing circuitry 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure (e.g., features described herein as rows may be arranged vertically and features described herein as columns may be arranged horizontally).

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another suitable example, the green pixels in a Bayer pattern are replaced by broadband image pixels having broadband color filter elements (e.g., clear color filter elements, yellow color filter elements, etc.). These examples are merely illustrative and, in general, color filter elements of any desired color and in any desired pattern may be formed over any desired number of image pixels 34.

If desired, array 32 may be part of a stacked-die arrangement in which pixels 34 of array 32 are split between two or more stacked substrates. In such an arrangement, each of the pixels 34 in the array 32 may be split between the two dies at any desired node within the pixel. As an example, a node such as the floating diffusion node may be formed across two dies. Pixel circuitry that includes the photodiode and the circuitry coupled between the photodiode and the desired node (such as the floating diffusion node, in the present example) may be formed on a first die, and the remaining pixel circuitry may be formed on a second die. The desired node may be formed on (i.e., as a part of) a coupling structure (such as a conductive pad, a micro-pad, a conductive interconnect structure, or a conductive via) that connects the two dies. Before the two dies are bonded, the coupling structure may have a first portion on the first die and may have a second portion on the second die. The first die and the second die may be bonded to each other such that first portion of the coupling structure and the second portion of the coupling structure are bonded together and are electrically coupled. If desired, the first and second portions of the coupling structure may be compression bonded to each other. However, this is merely illustrative. If desired, the first and second portions of the coupling structures formed on the respective first and second dies may be bonded together using any metal-to-metal bonding technique, such as soldering or welding.

As mentioned above, the desired node in the pixel circuit that is split across the two dies may be a floating diffusion node. Alternatively, the desired node in the pixel circuit that is split across the two dies may be the node between a floating diffusion region and the gate of a source follower transistor (i.e., the floating diffusion node may be formed on the first die on which the photodiode is formed, while the coupling structure may connect the floating diffusion node to the source follower transistor on the second die), the node between a floating diffusion region and a source-drain node of a transfer transistor (i.e., the floating diffusion node may be formed on the second die on which the photodiode is not located), the node between a source-drain node of a source follower transistor and a row select transistor, or any other desired node of the pixel circuit.

In general, array 32, row control circuitry 40, column control and readout circuitry 42, and control and processing circuitry 44 may be split between two or more stacked substrates. In one example, array 32 may be formed in a first substrate and row control circuitry 40, column control and readout circuitry 42, and control and processing circuitry 44 may be formed in a second substrate. In another example, array 32 may be split between first and second substrates (using one of the pixel splitting schemes described above) and row control circuitry 40, column control and readout circuitry 42, and control and processing circuitry 44 may be formed in a third substrate.

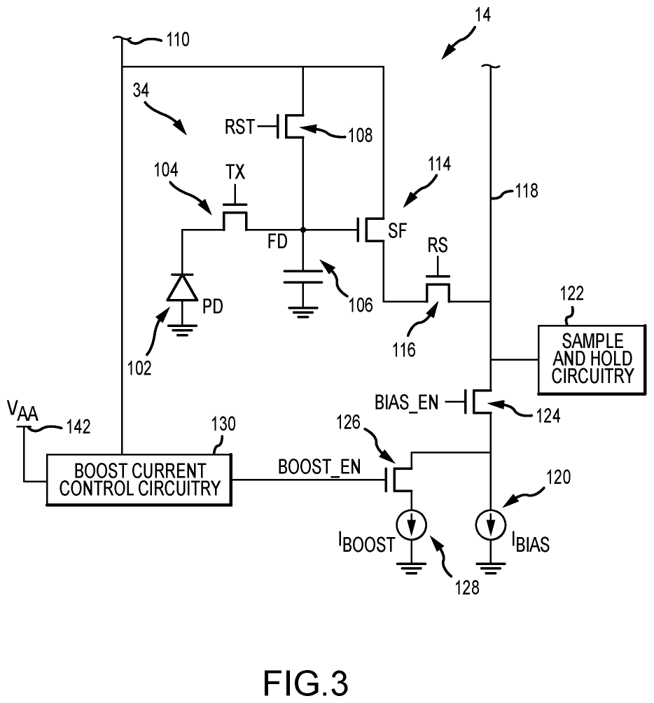

FIG. 3 is a diagram of an illustrative image sensor that includes an imaging pixel. As shown, image sensor 14 may include an imaging pixel 34. Imaging pixel 34 may include a photosensitive element 102 (e.g., a photodiode). Photosensitive element 102 has a first terminal that is coupled to ground. The second terminal of photosensitive element 102 is coupled to transfer transistor 104. Transfer transistor 104 is coupled to floating diffusion (FD) region FD with an associated floating diffusion capacitance 106. A reset transistor 108 may be coupled between floating diffusion region FD and voltage supply line 110. Supply line 110 (sometimes referred to as column supply line 110 or voltage supply line 110) may provide a supply voltage (V_{AA}) from voltage supply terminal 142. Photosensitive element 102 may be a doped semiconductor region (e.g., a region in a silicon substrate that is doped by ion implantation, impurity diffusion, or other doping process). Floating diffusion region FD may also be a doped semiconductor region.

Source follower transistor 114 (SF) has a gate terminal coupled to floating diffusion region FD and a first terminal of reset transistor 108. Source follower transistor 114 also has a first source-drain terminal coupled to voltage supply line 110. The first source-drain terminal of source follower transistor 114 is also coupled to boost current control circuitry 130. In this application, each transistor is illustrated as having three terminals: a source, a drain, and a gate. The source and drain terminals of each transistor may be changed depending on how the transistors are biased and the type of transistor used. For the sake of simplicity, the source and drain terminals are referred to herein as source-drain terminals or simply terminals. A second source-drain terminal of source follower transistor 114 is coupled to row select transistor 116. Sampling transistor 116 may be interposed between source follower transistor 114 and column output line 118 (sometimes referred to as column line 118).

Column output line 118 may be coupled to a current source such as current source 120. The current source may provide a first bias current (I_{BIAS}). A bias current enable transistor 124 is interposed between the column output line 118 and current source 120. Column output line 118 may also be coupled to an additional current source such as current source 128. Current source 128 may provide a second bias current (I_{BOOST}), sometimes referred to as a boosting bias current. A bias current boost enable transistor 126 is interposed between current source 128 and bias current enable transistor 124.

A gate terminal of transfer transistor 104 receives control signal TX. A gate terminal of reset transistor 108 receives control signal RST. A gate terminal of row select transistor 116 receives control signal RS. A gate terminal of bias current enable transistor 124 receives bias current enable signal BIAS_EN. A gate terminal of bias current boost enable transistor 126 receives boost enable signal BOOST_EN. Control signals TX, RST, and RS may be provided by row control circuitry (e.g., row control circuitry 40 in FIG. 2) over control paths (e.g., control paths 36 in FIG. 2). Control signal BIAS_EN may be provided by control and processing circuitry (e.g., control and processing circuitry 44 in FIG. 2) over control paths (e.g., data and control path 26 in FIG. 2). Control signal BOOST_EN may be provided by boost current control circuitry 130. Boost current control circuitry 130, sample and hold circuitry 122, transistors 124 and 126, and current sources 120 and 128 may all be considered column control and readout circuitry (e.g., column control and readout circuitry 42 in FIG. 2).

When it is desired to sample a signal from the floating diffusion region FD, row select transistor 116 may be asserted. After the row select transistor is asserted, sample and hold circuitry 122 may be used to obtain and store the voltage of column output line 118 that is indicative of the voltage on floating diffusion region FD. However, there may be a delay between asserting row select transistor 116 and the settling of the voltage of column output line 118. This delay may sometimes be referred to as the settling time. In general, the settling time may be inversely proportional to the magnitude of the total bias current provided by current sources 120 and/or 128.

Consider an example in which only current source 120 is used to apply current to the column output line (and the total bias current therefore equals I_{BIAS}). As the magnitude of I_{BIAS} increases, the settling time associated with sampling a voltage onto column output line 118 decreases. Therefore, a large I_{BIAS} may ensure that the settling time is fast enough for unattenuated readout even at fast frame rates and high resolution. However, despite desirably decreasing the settling time, increasing bias current I_{BIAS} may also undesirably increase power consumption, reduce output swing, and increase noise.

To decrease settling time while mitigating power consumption, the image sensor of FIG. 3 allows for selective increasing of the total bias current applied to the column output line using optional secondary current source 128 and boost current control circuitry 130. Boost current control circuitry 130 may be configured to selectively assert boost enable transistor 126. When boost enable transistor 126 is asserted, the bias current I_{BOOST} from current source 128 is applied to column output line 118. The total bias current applied to column output line 118 is therefore increased from I_{BIAS} (when boost enable transistor 126 is not asserted) to the sum of I_{BIAS} and I_{BOOST} (when boost enable transistor 126 is asserted).

Boost current control circuitry 130 may be configured to apply the current boost only when the total bias current is identified as being too low. This ensures that the settling time is fast enough for unattenuated readout even at fast frame rates and high resolution. However, because the boost current is only applied when needed, power consumption is minimized.

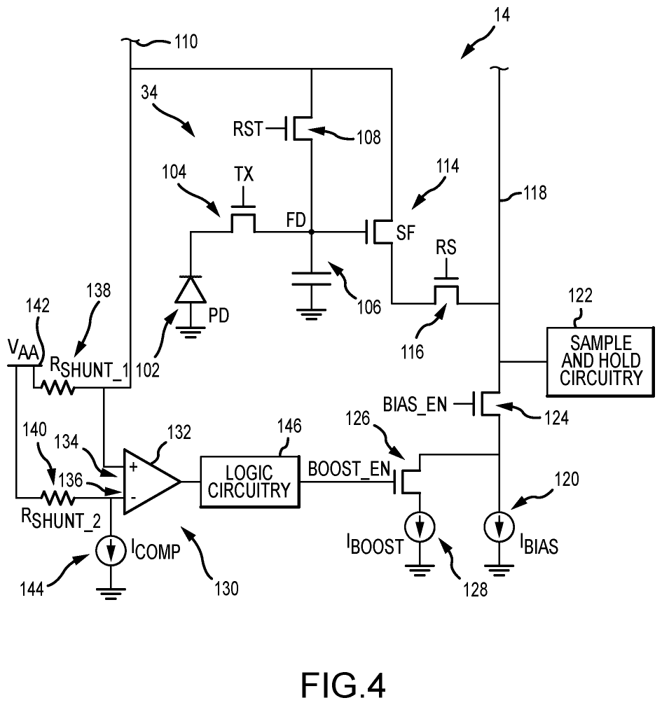

FIG. 4 is a diagram of the illustrative image sensor of FIG. 3 with a detailed depiction of one possible arrangement for boost current control circuitry 130. As shown in FIG. 4, boost current control circuitry 130 may include a comparator 132, resistors 138 and 140, bias voltage supply terminal 142, current source 144, and logic circuitry 146. Comparator 132 has first and second input terminals 134 and 136. Input terminal 134 is coupled to resistor 138 (R_{SHUNT_1}), which is sometimes referred to as shunt resistor 138. Input terminal 136 is coupled to resistor 140 (R_{SHUNT_2}), which is sometimes referred to as shunt resistor 140. Input terminal 134 may be coupled to source follower transistor 114. Input terminal 136 may be coupled to current source 144.

Resistor 138 is interposed between input terminal 134 and voltage supply terminal 142 (which provides power supply voltage V_{AA} to supply line 110). Resistor 140 is interposed between input terminal 136 and the voltage supply terminal 142. The output of comparator 132 is provided to logic circuitry 146. Logic circuitry 146 may output the boost current enable signal BOOST_EN to a gate terminal of transistor 126 based on the output of the comparator.

Resistors 138 and 140 may have low resistivities so that they do not affect the readout. Any desired resistance values may be used for each of resistors 138 and 140. The resistance of resistor 138 may be the same as the resistance of resistor 140 or may be different than the resistance of resistor 140. The example of a resistor being used in FIG. 4 is merely illustrative. If desired, another type of circuit component that is able to measure current (e.g., a diode-connected transistor) may be used.

Comparator 132 allows for a comparison between the actual supply current for the imaging pixel and a target supply current for the imaging pixel. Input terminal 134 of the comparator is coupled to the pixel through source follower transistor 114. This input terminal therefore measures the actual current applied to the pixel. Input terminal 136 is coupled to current source 144, which provides a bias voltage I_{COMP} (sometimes referred to as a reference voltage or a comparison voltage). Bias voltage I_{COMP} may be set to a target value for the current running through pixel 34. If the actual current is too low, boost current I_{BOOST} may be applied to the pixel to help the column line settle to the point where the current through pixel equals the target current value I_{COMP}. Once the actual current matches the target current value, the boost current may be removed to conserve power.

Logic circuitry 146 may use the output of comparator 132 to determine a boost enable control signal BOOST_EN to provide to transistor 126. There are numerous possible ways for logic circuitry 146 to assert and deassert transistor 126. In one possible scenario, logic circuitry 146 may default to asserting transistor 126 during a readout period. Once comparator 132 indicates that the actual current through the pixel matches the target current, logic circuitry 146 may then deassert transistor 126.

In another possible scheme, logic circuitry 146 may default to deasserting transistor 126 during a readout period and may only assert transistor 126 to apply the boost current if the comparator indicates that the actual current is lower than the target current. In this scenario, the logic circuitry may wait for a given delay time before assessing if the actual current is too low. For example, the logic circuitry defaults to turning off the boost current then, after the delay time, if the actual current is still lower than the target current, the logic circuitry turns on the boost current by asserting transistor 126.

Logic circuitry 146 may also only switch the boost enable control signal on and off once during a given readout. This may ensure that the current source is not rapidly turned on and off in an undesirable manner.

It should be understood that the example of FIG. 4 in which only one of the imaging pixels in the image sensor is depicted is merely illustrative. Image sensor 14 includes a plurality of rows and a plurality of columns of imaging pixels (as shown in FIG. 2). Each column output line may be coupled to the row select transistor of each imaging pixel in a respective column of imaging pixels. Similarly, input terminal 134 of comparator 132 is coupled to a respective column of imaging pixels (e.g., input terminal 134 is coupled to the source follower transistor of each imaging pixel in a respective column of imaging pixels).

Logic circuitry 146 may include any desired components. For example, logic circuitry 146 may include one or more AND gates, one or more OR gates, one or more NAND gates, one or more NOR gates, one or more inverters, one or more XOR gates, one or more comparators, one or more digital-to-analog converters, one or more analog-to-digital converters, one or more transistors, etc. Logic circuitry 146 may include digital logic components and/or analog components.

Sample and hold circuitry 122 may include any desired components. For example, sample and hold circuitry 122 may include one or more capacitors, one or more analog-to-digital converters, one or more digital-to-analog converters, one or more comparators, one or more reference voltage supplies, etc.

The magnitude of the current I_{COMP} provided by current source 144 may be adjustable. The magnitude of I_{COMP} may be updated during operation of the image sensor to be any desired current. The magnitude of I_{COMP} may be adjusted by logic circuitry 146, by row control circuitry 40, or by any other desired control circuitry in the image sensor. In one illustrative example, the magnitude of I_{COMP} may be set equal to the magnitude of I_{BIAS} from current source 120. However, other desired magnitudes may be used if desired.

The magnitude of the current I_{BOOST} from current source 128 may be larger than the magnitude of the current I_{BIAS} from current source 120. I_{BOOST} may be more than two times greater than IBIAS, more than three times greater than I_{BIAS}, more than five times greater than I_{BIAS}, more than ten times greater than I_{BIAS}, less than twenty times greater than I_{BIAS}, between two and ten times greater than I_{BIAS}, between four and twelve times greater than I_{BIAS}, etc. I_{BOOST} and I_{BIAS} may both optionally be adjustable. The magnitude of I_{BOOST} and/or I_{BIAS} may be adjusted by logic circuitry 146, by row control circuitry 40, or by any other desired control circuitry in the image sensor.

In some cases, I_{BIAS} may be equal to 0. Current source 120 may therefore optionally be omitted entirely if desired. When I_{BIAS} is equal to 0, the image sensor may rely only on boost current I_{BOOST} to serve as the bias current during settling of the column output line. The boost current may still be controlled by logic circuitry 146 in a similar manner to when I_{BIAS} is greater than 0.

Providing the optional boost current capabilities as in FIG. 4 may allow for bias current I_{BIAS} to be lower than if the boost current was not present. This has the additional benefit of reducing noise and allowing for a larger voltage swing (because the lower I_{BIAS} is used at the point of sampling).

It should be understood that each column of imaging pixels may have respective boost current control circuitry 130. In other words, each column of pixels will have a single respective comparator 132, associated logic circuitry 146, etc.

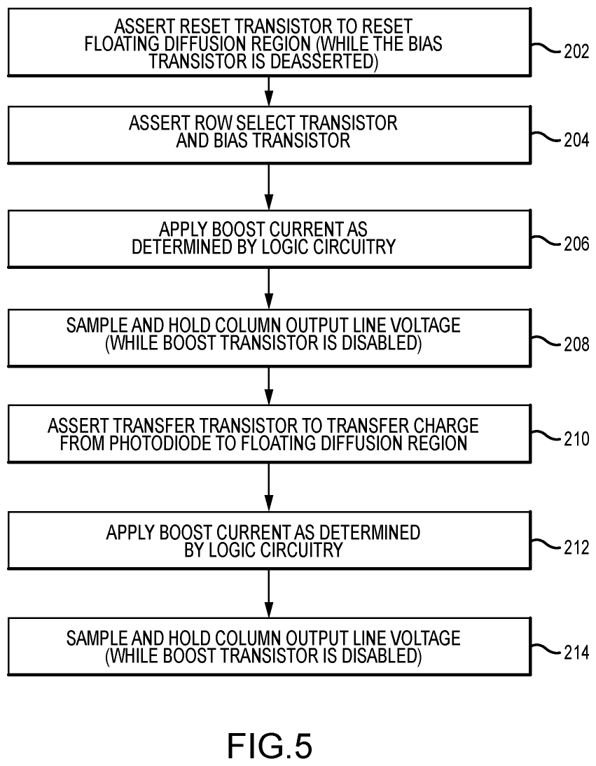

FIG. 5 is a flowchart showing illustrative steps for operating the image sensor of FIG. 4 during a double sampling readout. In double sampling, a reset value and a signal value are obtained during readout. The reset value may then be subtracted from the signal value during subsequent processing to help correct for noise. The double sampling may be correlated double sampling (in which the reset value is sampled before the signal value) or uncorrelated double sampling (in which the reset value is sampled after the signal value is sampled). Specifically, a correlated double sampling readout is described in connection with FIG. 5. However, it should be noted that other types of readout may be performed using the image sensor of FIG. 4.

Before readout, photodiode 102 may accumulate charge in response to incident light. When is time for readout to occur, reset transistor 108 may be asserted at step 202. Asserting reset transistor 108 may reset floating diffusion region FD to a reset voltage. Bias current enable transistor 124 may be deasserted during step 202.

At step 204, row select transistor 116 and bias current enable transistor 124 may be asserted. Asserting row select transistor 116 and bias current enable transistor 124 may cause column output line 118 to settle to an output voltage that is indicative of the voltage on floating diffusion region FD. To decrease the settling time of the column output line (e.g., to reduce the length of time it takes for the column output line to reach the output voltage), boost current I_{BOOST} may optionally be applied at step 206. Logic circuitry 146 may use the output from comparator 132 to determine when to assert boost current enable transistor 126 during step 206. When boost current enable transistor 126 is asserted, the boost current from current source 128 is applied to the column output line in addition to the bias current from current source 120. Transistor 124 may remain asserted throughout step 206 (e.g., transistor 124 remains asserted even when transistor 126 is deasserted).

At step 208, after column output line 118 has settled to the output voltage, sample and hold circuitry 122 may sample and hold the column output line voltage. This sample may be referred to as the reset sample, reset signal, or reset voltage (as the column output line voltage is indicative of the reset voltage on floating diffusion region FD). Boost current enable transistor 126 may be disabled during step 208.

At step 210, transfer transistor 104 may be asserted. When the transfer transistor is asserted, charge may be transferred from photodiode 102 to floating diffusion region FD. This causes a corresponding change in the voltage at the floating diffusion region, which causes a corresponding change in the column output line voltage. The length of time it takes for the column output line to settle to the new column output line voltage is again referred to as settling time. To decrease the settling time of the column output line (e.g., to reduce the length of time it takes for the column output line to reach the new column output line voltage), boost current I_{BOOST} may optionally be applied at step 212. Logic circuitry 146 may use the output from comparator 132 to determine when to assert boost current enable transistor 126 during step 212. When boost current enable transistor 126 is asserted, the boost current from current source 128 is applied to the column output line in addition to the bias current from current source 120. Transistor 124 may remain asserted throughout step 212 (e.g., transistor 124 remains asserted even when transistor 126 is deasserted). Transistor 124 may be asserted during step 210 or may be deasserted during step 210. If transistor 124 is deasserted during step 210, transistor 124 may be asserted at the end of step 210 and throughout step 212.

At step 214, after column output line 118 has settled to the output voltage, sample and hold circuitry 122 may sample and hold the column output line voltage. This sample may be referred to as the integration sample, integration signal, integration voltage, or signal voltage (as the column output line voltage is indicative of the amount of charge accumulated in the photodiode during the integration time). Boost current enable transistor 126 may be disabled during step 214. The reset sample may be subtracted from the integration sample during subsequent processing to determine the amount of charge that accumulated in the photodiode during the integration time.

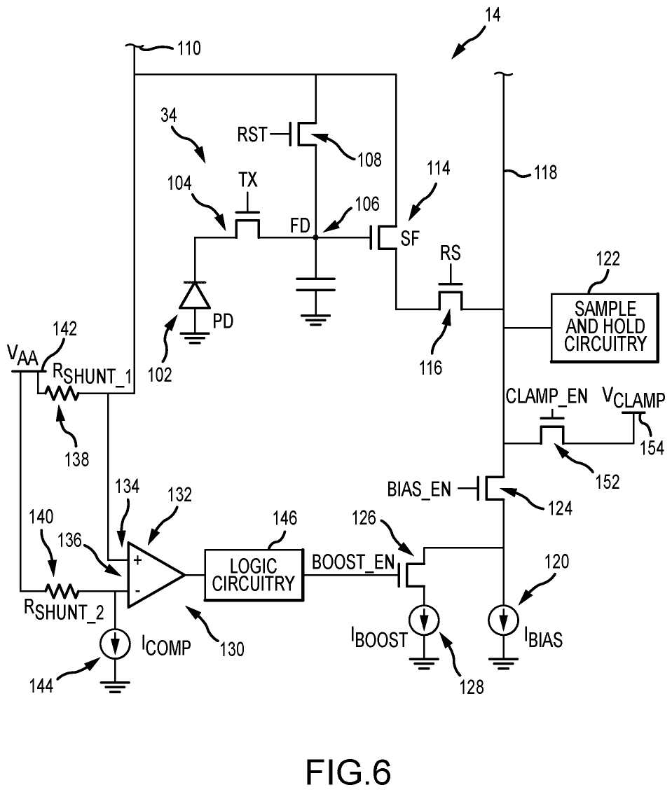

If desired, the image sensor of FIG. 4 may include optional clamping circuitry. An arrangement of this type is shown in FIG. 6. The image sensor of FIG. 6 is the same as the image sensor of FIG. 4, except for the addition of clamping enable transistor 152 and clamp voltage supply terminal 154 in FIG. 6. The clamping enable transistor 152 may receive a clamping enable signal CLAMP_EN. Control signal CLAMP_EN may be provided by row control circuitry (e.g., row control circuitry 40 in FIG. 2) over control paths (e.g., control paths 36 in FIG. 2). Clamp voltage supply terminal 154 may supply a clamping voltage V_{CLAMP}.

Asserting clamping enable transistor 152 may clamp the column output line to voltage V_{CLAMP}. This may ensure that the column output line does not drop below V_{CLAMP}. The clamping transistor may optionally be asserted during step 202 of FIG. 5, deasserted during steps 204, 206, and 208 of FIG. 5, asserted during step 210 of FIG. 5, and deasserted during steps 212 and 214 of FIG. 5. Clamping voltage V_{CLAMP} may be adjustable. For example, the magnitude of V_{CLAMP} may be adjusted by logic circuitry 146, by row control circuitry 40, or by any other desired control circuitry in the image sensor.

In FIGS. 3, 4, and 6, bias current boost enable transistor 126 is depicted as being interposed between current source 128 and bias current enable transistor 124. This example is merely illustrative. If desired, bias boost enable transistor 126 may instead be interposed between current source 128 and column output line 118 (without transistor 124 intervening).

It should be noted the arrangement of pixel 34 herein is merely illustrative. In general, any desired pixel circuitry may be used with the boost current control circuitry shown in connection with FIGS. 3-6. The pixel circuitry may include an anti-blooming transistor, a dual conversion gain transistor, a dual conversion gain capacitor, one or more overflow capacitors, one or more overflow transistors, one or more charge storage regions in addition to the floating diffusion region, etc. The boost current control circuitry of FIGS. 3-6 may be used in an image sensor that operates with a rolling shutter (in which each row of pixels sequentially captures an image) or a global shutter (in which every pixel in the image sensor simultaneously captures an image).

The foregoing is merely illustrative of the principles of this invention and various modifications can be made by those skilled in the art. The foregoing embodiments may be implemented individually or in any combination.

What is claimed is:

1. An image sensor comprising:
imaging pixels;
a column output line that is coupled to a column of the imaging pixels;
a first current source that is coupled to the column output line during readout;
a second current source; and
control circuitry configured to selectively couple the second current source to the column output line during readout.

2. The image sensor defined in claim 1, further comprising:
a transistor that is interposed between the second current source and the column output line, wherein the control circuitry is configured to selectively assert the transistor during readout.

3. The image sensor defined in claim 2, further comprising:
an additional transistor that is interposed between the first current source and the column output line, wherein the transistor is coupled between the additional transistor and the second current source.

4. The image sensor defined in claim 2, wherein the control circuitry comprises a comparator having a first input terminal coupled to the column of imaging pixels and a second input terminal coupled to a third current source.

5. The image sensor defined in claim 4, wherein the control circuitry comprises logic circuitry that receives an output from the comparator and that provides a control signal to a gate terminal of the transistor.

6. The image sensor defined in claim 5, wherein the third current source is coupled to a bias voltage supply terminal and wherein a first component having a first resistance is interposed between the bias voltage supply terminal and the third current source.

7. The image sensor defined in claim 6, wherein a second component having a second resistance is interposed between the bias voltage supply terminal and the first input terminal of the comparator.

8. The image sensor defined in claim 1, wherein the control circuitry is configured to increase a total bias current applied to the column output line and decrease a settling time for the column output line by coupling the second current source to the column output line during readout.

9. The image sensor defined in claim 8, wherein the control circuitry is configured to decouple the second current source from the column output line after determining that the column output line has settled to an output voltage.

10. The image sensor defined in claim 1, wherein the first current source provides a first bias current having a first magnitude, wherein the second current source provides a second bias current having a second magnitude, and wherein the second magnitude is at least three times greater than the first magnitude.

11. The image sensor defined in claim 1, further comprising:
a bias voltage supply terminal that is configured to supply a clamping voltage; and
a clamping enable transistor that is interposed between the column output line and the bias voltage supply terminal.

12. An image sensor comprising:
an array of imaging pixels;
a column output line that is coupled to a column of the imaging pixels;
a first current source;
a first transistor that is interposed between the first current source and the column output line;
a second current source;
a second transistor that is interposed between the second current source and the first transistor; and
boost current control circuitry configured to selectively assert the second transistor.

13. The image sensor defined in claim 12, wherein the boost current control circuitry comprises a comparator having first and second inputs and wherein the second input of the comparator is coupled to a bias voltage supply terminal and a third current source.

14. The image sensor defined in claim 13, wherein the third current source is configured to provide a current having an adjustable magnitude.

15. The image sensor defined in claim 13, wherein the first input of the comparator is coupled to the bias voltage supply terminal and each imaging pixel in the column of imaging pixels.

16. The image sensor defined in claim 15, wherein each imaging pixel in the column of imaging pixels has a photodiode, a source follower transistor, a floating diffusion region coupled to a gate of the source follower transistor, and a transfer transistor interposed between the photodiode and the floating diffusion region and wherein the first input of the comparator is coupled to the source follower transistor of each imaging pixel in the column of imaging pixels.

17. The image sensor defined in claim 16, wherein the boost current control circuitry comprises a first resistor that is coupled between the bias voltage supply terminal and the first input of the comparator and wherein the boost current control circuitry comprises a second resistor that is coupled between the bias voltage supply terminal and the second input of the comparator.

18. The image sensor defined in claim 15, wherein the boost current control circuitry comprises logic circuitry and wherein the comparator has an output that is provided to the logic circuitry.

19. The image sensor defined in claim 18, wherein the logic circuitry is configured to provide a boost current enable control signal to a gate terminal of the second transistor.

20. An image sensor comprising:
an array of imaging pixels arranged in a plurality of rows and a plurality of columns;
a plurality of column output lines, wherein each column output line is coupled to a respective column of imaging pixels;
a plurality of first current sources, wherein each first current source is coupled to a respective column output line;
a plurality of second current sources; and
a plurality of control circuits, wherein each control circuit is coupled to a respective column of imaging pixels and wherein each control circuit is configured to selectively couple a respective second current source to a respective column output line.
